(19) United States
(12) Patent Application Publication
(10) Pub. No.: US 2009/0077293 A1
(43) Pub. Date: Mar. 19, 2009

(54) Dimm Ejection Mechanism

(75) Inventors: Brian Michael Kerrigan, Cary, NC (US); Tony Carl Sass, Fuquay Varina, NC (US)

Correspondence Address: IBM CORPORATION (SS/NC);c/o STREETS & STEELE, 13831 NORTHWEST FREEWAY, SUITE 355, HOUSTON, TX, 77040, US

(73) Assignee: INTERNATIONAL BUSINESS MACHINES CORPORATION, Armonk, NY (US)

(21) Appl. No.: 11/851,445

(22) Filed: Sep. 7, 2007

(51) Int. Cl. H01R 13/62; H05K 5/00; H05K 7/10

(52) U.S. Cl. 710/301; 439/159; 439/160

(57) ABSTRACT

A connector for an electronic card includes an improved latching mechanism for facilitating the insertion and removal of the card. In one embodiment, a connector body is secured to a motherboard and has a socket for removably receiving a DIMM to a seated position. In the seated position, DIMM terminals are in electrical contact with socket terminals, placing the DIMM in electronic communication with the motherboard. A lever is pivotally coupled to an end of the connector body, and is pivotable into engagement with the DIMM to raise the DIMM. A linear actuator is movably secured on a track and is movable into engagement with the lever. A user ejects the DIMM by pressing downward on the linear actuator at a push point. In response, the linear actuator engages the lever to cause the lever to raise the DIMM from the seated position to a raised position, thereby separating electrical contact between the DIMM terminals and the socket terminals.

### BACKGROUND OF THE INVENTION

1. Field of the Invention

The present invention relates generally to connectors for removable electronic cards, and more particularly to a DIMM connector disposed on a motherboard.

2. Description of the Related Art

Computer system such as PCs and servers typically include a central or primary circuit board, commonly referred to as a “motherboard,” “baseboard,” or “system board,” providing electrical pathways by which motherboard components communicate. Motherboard components include processors, drive controllers, video controllers, primary memory, interrupt controllers, and BIOS, as well as electronic connectors for interfacing with additional components. An “electronic card” generally refers to any of a variety of circuit boards that may be removably coupled to the motherboard using electronic connectors to provide electronic communication (i.e. the transfer of power and signal information) between the electronic card and the motherboard. An electronic card may be mounted to the motherboard at an angle, such as at a 90-degree angle with respect to the motherboard. Common examples of electronic cards include expansion cards, such as peripheral component interconnect (PCI) expansion cards, and memory modules, such as dual in-line memory modules (DIMMs). Electronic cards may also be found in other types of electronic applications, such as in gaming consoles. DIMMs and other electronic cards include electrical contacts along one edge that mate with electrical contacts disposed in the slot of a corresponding “edge connector” on the motherboard, to provide electronic communication between the electronic card and the motherboard.

The design of connectors for DIMMs (i.e., DIMM connectors) is one area of continued development in the field of circuit board design. The present industry standard latching mechanism for a DIMM connector includes a latch at each end of the connector. These conventional latches are operable by hand, allowing a person to secure or release a DIMM with the person's fingers. FIG. 1 is a front view of a conventional DIMM connector 12 disposed on a motherboard 5 of a computer, with an exemplary VLP (Very Low Profile) DIMM 10 inserted into a slot-shaped socket of the connector 12. The VLP DIMM 10 is further detailed in FIG. 2 for reference, and includes a plurality of memory chips 2 and a plurality of electrical contacts or “DIMM terminals” 3 along one edge. The socket of the connector 12 frictionally receives that edge of the VLP DIMM 10. Socket terminals disposed within the slot of the connector 12 electrically contact the DIMM terminals 3 when the VLP DIMM 10 is fully seated within the connector 12. The socket terminals are also in electrical contact with leads on the motherboard to other motherboard components. Thus, the VLP DIMM 10 may communicate electronically with other motherboard components when full seated within the connector 12.

The VLP DIMM 10 has a smaller form factor than a conventional DIMM, which is particularly desired in applications wherein space above the motherboard is at a premium. However, the connector 12 includes industry standard DIMM latches 14 that are similarly able to latch a full-height DIMM connector. The latches 14 each include a lever 15 pivotally secured to the connector 12. The pivot axis of each lever 15 is generally perpendicular to the longitudinal face 11 of the VLP DIMM 10, so that the levers 15 pivot in a plane generally parallel to the longitudinal face 11 of the VLP DIMM 10. To release the VLP DIMM 10 from the connector 12, a user pivots each lever 15 outwardly, away from one another, with direct contact by the user's fingers 16A, 16B (e.g. the index finger of each hand). This outward movement of the levers 15 requires the fingers 16A, 16B to also move outwardly, away from one another.

While the prior art design of the connector 12 and latch 14 provides satisfactory retention and removal of the VLP DIMM 10, the outward movement of the levers 15 requires additional clearance about the VLP DIMM 10, as designated by reference dimension “A.” This requisite clearance must take into account both the width of the user's fingers 16A, 16B and the lateral, outward distance each lever 15 moves when operating the levers 15 to release the VLP DIMM 10. The effective length “L” of the connector 12 is defined here as the distance along the motherboard that is allocated for the connector 12 and operation thereof. The effective length L includes the anticipated width of the user's fingers 16A, 16B required to operate the levers 15. The clearance required to accommodate this outward movement also increases the projected surface area (“footprint”) of the motherboard that must be allocated to the connector 12 and its operation. The increased clearance required around the latches is an inefficient use of the limited surface area on a motherboard and results in less than ideal packaging density.

Therefore, improved DIMM connectors are needed. One area for improvement would be to reduce the footprint of DIMM connectors. For example, a DIMM connector that provides simple and reliable operation with less effort than currently known connectors would be desirable. It would also be desirable to develop a DIMM connector that increased the speed and ease of computer assembly and repair, and enhanced user serviceability.

### SUMMARY OF THE INVENTION

The present invention includes an improved connector, latching mechanism, and method for installing and uninstalling an electronic card, such as a DIMM. A first embodiment provides a connector body configured for being secured to a circuit board. The connector body has a socket for removably receiving the electronic card in a seated position for electronic communication with the circuit board. A latching mechanism includes a lever pivotally coupled to an end of the connector body about a pivot axis, and a linear actuator movably secured on a track. The lever includes a card-engagement portion of the lever spaced from the pivot axis. The lever is pivotable about a pivot axis to move the card-engagement portion of the lever into upward engagement with the electronic card, to raise the electronic card away from the seated position. The linear actuator is linearly movable along the track toward the circuit board into engagement with another portion of the lever opposite the card-engagement portion with respect to the pivot axis, to cause the card-engagement portion of the lever to raise the electronic card from the seated position to a raised position.

A second embodiment provides a computer system that includes a motherboard having a plurality of electronic motherboard components. A memory module card has a plurality of electronic memory module terminals along an edge of the memory module card. A memory module connector is secured to the motherboard and has a slot-shaped memory module socket and a plurality of electronic socket terminals. The memory module socket is configured for removably receiving an edge of the memory module. The memory module is movable between a seated position in which the memory module terminals are in electrical contact with corresponding socket terminals and a raised position wherein the memory module terminals are separated from the socket terminals. A lever is pivotally coupled to an end of the connector body, and is pivotable into engagement with the memory module card to move the memory module card within the memory module socket. A linear actuator is movably secured on a track and linearly movable along the track into engagement with the lever to cause the lever to move the electronic card from the seated position to the raised position.

A third embodiment provides a method of removably installing a memory module card on a circuit board, such as a motherboard. An edge of the memory module card having a plurality of electronic memory module terminals is inserted into a slot-shaped memory module socket having a corresponding plurality of electronic socket terminals. The memory module card is moved within the memory module socket to a seated position in which the memory module terminals are in electrical contact with corresponding socket terminals. While the memory module card is moved to the seated position, a lever is engaged by the memory module card to pivot the lever in a first direction about a pivot point. While pivoting the lever about the pivot point, a linear actuator is engaged by the lever, to linearly move the linear actuator along a track to an upper position of the linear actuator. The memory module card may be subsequently removed by pressing the linear actuator to move the linear actuator from the raised position to a lowered position. Moving the linear actuator in this manner engages the lever to pivot the lever about the pivot point in a second direction opposite the first direction. Pivoting the lever in this manner engages the memory module card with the lever to move the memory module card from the seated position to a raised position separating electrical contact between the memory module terminals and the socket terminals.

Other embodiments, aspects, and advantages of the invention will be apparent from the following description and the appended claims.

### BRIEF DESCRIPTION OF THE DRAWINGS

FIG. 1 is a side view of a conventional VLP DIMM connector disposed on a motherboard with an exemplary VLP DIMM inserted.

FIG. 2 is a side view of the VLP DIMM.

FIG. 3A is a perspective end view of an exemplary DIMM connector according to one embodiment of the invention.

FIG. 3B is a detailed perspective view of a portion of the latching mechanism as outlined in FIG. 3A.

FIG. 4 is a partially cutaway perspective view of the latching mechanism with the linear actuator in an upper position that corresponds to the DIMM being in the fully seated position within the connector.

FIG. 5 is a partially cutaway perspective view of the latching mechanism with the linear actuator in a lowered position, and with the DIMM in a raised position substantially withdrawn from the connector.

FIG. 6 is a side view of the VLP DIMM connector with the VLP DIMM inserted, demonstrating the reduced size of the VLP DIMM connector as compared with the conventional VLP DIMM connector of FIG. 1.

### DETAILED DESCRIPTION OF PREFERRED EMBODIMENTS

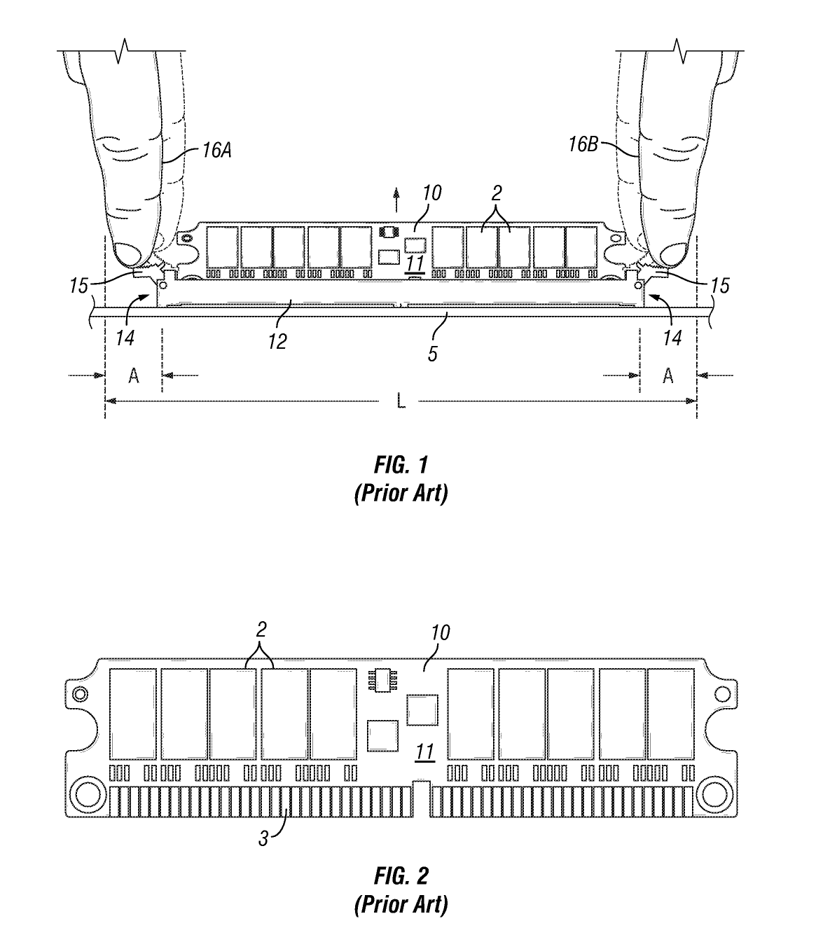

The present invention provides a connector having an improved latching mechanism for facilitating the insertion and removal of an electronic card (alternatively referred to as a “card”) within the connector. The latching mechanism provides the connector with a reduced size, e.g. a smaller footprint and/or reduced volume as compared to prior art connectors, such as the DIMM connector 12 of FIG. 1. The reduced size of a connector according to the invention is especially useful as applied to VLP-type DIMM connectors, for which minimizing space and size requirements is particularly desirable. Thus, the invention is described extensively in the context of VLP DIMM connectors. However, the invention also provides connectors for other types of DIMMS, such as full-height DIMMs. Connectors for other electronic cards, such as expansion cards, are also within the scope of the invention.

One embodiment provides a VLP DIMM connector having a novel latching mechanism (“latch”). The connector includes a connector body secured to a circuit board, such as a motherboard. A slot-shaped socket (“slot”) removably receives a VLP DIMM, to mechanically secure the VLP DIMM in a fully seated position wherein the VLP DIMM is in electronic communication with the motherboard. The slot is typically oriented perpendicular to the motherboard so that the VLP DIMM is oriented perpendicular to the motherboard when in a fully seated position. However, the connector may be formed with the slot being at another desired angle with respect to the motherboard. The latching mechanism includes a lever pivotally coupled to an end of the connector body about a pivot axis. The lever is pivotable to move a portion of the lever below the pivot axis into engagement with a lower edge of the electronic card to raise the electronic card. The latching mechanism also includes a linear actuator interleaved with the lever and which extends above the lever in a direction away from the motherboard. The linear actuator is movably secured on a track and is linearly movable along the track into engagement with a portion of the lever above the pivot axis by pressing down on the linear actuator at a push point. Pressing down on the linear actuator to engage the lever in this manner causes the lever to raise the electronic card from the fully seated position to a raised position, wherein the electronic terminals on the DIMM (“DIMM terminals”) are separated from the electronic terminals in the socket (“socket terminals”). Moving the DIMM from the fully seated position to the raised position may fully de-couple the DIMM from the connector, so that the DIMM is completely out of the socket. Alternatively, a portion of the DIMM may remain supported in the socket while in the raised position. Any frictional engagement between the DIMM and the DIMM socket may be less in the raised position than in the fully seated position, so that a user may more easily retrieve the DIMM from the connector once the DIMM is in the raised position.

The presently described embodiment may further include a relief channel defined by the linear actuator, with a portion of the lever being movably disposed in the relief channel during at least a portion of the range of movement of the lever and linear actuator that moves the electronic card from the fully seated position to the raised position. The relief channel is typically a slit. The linear actuator need not be coupled to the lever, but rather may slide freely along a contact surface of the lever when the linear actuator is pressed down against the contact surface. Pressing on the linear actuator in this manner rotates the lever, during which a portion of the lever may move within the relief channel rather than binding or locking up. A retention tab is provided on the lever to move into a notch conventionally provided on the DIMM to retain the electronic card while in the fully seated position. The latching mechanism therefore requires less space to operate by virtue of this interleaved latching mechanism design. The interleaved design further reduces the required part clearance around the latching mechanism to increase packaging density and allows for a reduced height wherein the linear actuator does not increase the overall connector height.

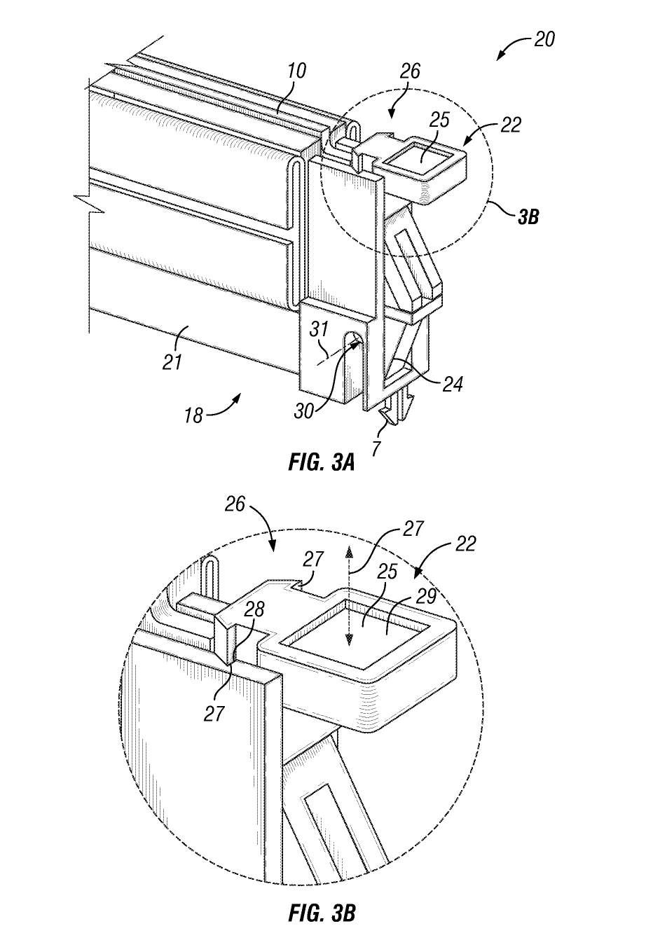

FIG. 3A is a perspective end view of an exemplary DIMM connector 18 according to one embodiment of the invention. The connector 18 includes a connector body 21 that may be mechanically secured and electronically connected to a motherboard, such as the motherboard 5 of FIG. 1. As with some prior art DIMM connectors, retention tabs 7 are provided on the connector body 21 to mechanically secure the connector 18 to the motherboard. The connector body 21 may removably receive a DIMM, such as the conventional VLP DIMM 10 of FIG. 2. The VLP DIMM 10 is fully seated in a slot-shaped socket (“slot”) of the connector 18, as shown, with the DIMM terminals electrically contacting the connector terminals to place the DIMM in electronic communication with the motherboard. The connector 18 includes a latching mechanism 20 at the end of the connector 18 shown in FIG. 3A. Another, substantially identical latching mechanism is typically included at the other end of the connector 10 (not shown). The latching mechanisms 20 may be operated simultaneously to mechanically and/or electronically de-couple the VLP DIMM 10 from the connector by raising the VLP DIMM 10 vertically with respect to the connector body 21. This operation of the latching mechanism(s) 20 may be described as ejecting the VLP DIMM 10, even if the VLP DIMM 10 remains partially inserted in the connector 18.

The latching mechanism 20 includes a linearly-movable element (“linear actuator”) 22 and a rotatable element (“lever”) 24 that cooperate to eject the VLP DIMM by raising the VLP DIMM 10 in response to a user pushing down on the linear actuator 22. The linear actuator 22 is coupled to a guide or “track” 26 that guides the linear actuator 22 in a generally linear trajectory, perpendicularly toward or away from the motherboard. The lever 24 is pivotally coupled to the connector body 21 and is constrained to pivot about an axis 31. A user may apply a force to the linear actuator 22 by pressing downward (i.e. toward the motherboard) with the user's finger on the linear actuator at a push point 25. This downward force causes the linear actuator 22 to move along the track 26 into engagement with a portion of the lever 24 above the pivot axis. The engagement of the linear actuator 22 against the lever 24 rotates (i.e. “pivots”) the lever 22 about the axis 31. As the lever 24 rotates, the lever 24 raises the VLP DIMM 10 out of the slot on the connector 18, away from the motherboard. The VLP DIMM 10 may be raised in response to pressing down on the linear actuator 24 sufficiently to separate the DIMM terminals from the socket terminals, to separate electronic communication between the VLP DIMM 10 and the motherboard. Pressing down on the linear actuator 22 may also at least partially remove the VLP DIMM 10 from the slot, or displace the VLP DIMM 10 sufficiently within the slot to a position of reduced frictional engagement between the slot and the VLP DIMM 10. The operation of the latching mechanism 20 is further detailed below.

FIG. 3B is a detailed perspective view of the portion of the latching mechanism 20 outlined in FIG. 3A. The push point 25 includes an optional recess 29, which is rectangular in this embodiment, but which is not limited by the invention to having any particular shape. The push point 25 may also be knurled or textured or have other attributes for increasing the grip between the user's finger and the push point 25. While these features may improve the grip between the user's finger and the push point 25, they are not required to operate the latching mechanism 20 as intended. The track 26 in this embodiment may be described by virtue of its cross-sectional shape as having a “dovetail” or other linear guideway feature that may preferably include two tapered flanges 27 on the linear actuator 22 retained by a shoulder 28 of the connector body 21. Thus, the track 26 constrains the linear actuator 22 to linear translational movement in the linear direction indicated at 23. While a reverse dovetail connection is shown, other types of linear guides or tracks will be available to one skilled in the art for so constraining the linear actuator 22 to linear movement in the direction indicated. For example, a linear “boxed” guideway may be used to constrain the linear actuator 22 to linear movement into or out of engagement with the lever 24. In any of its possible configurations the track 26 may guide movement of the linear actuator 22 in a direction directly toward or away from the motherboard in response to being pressed by the user. This avoids any appreciable outward movement of the user's finger(s) and the linear actuator 22, which reduces the required part clearance around the latching mechanism 20 and increase packaging density accordingly.

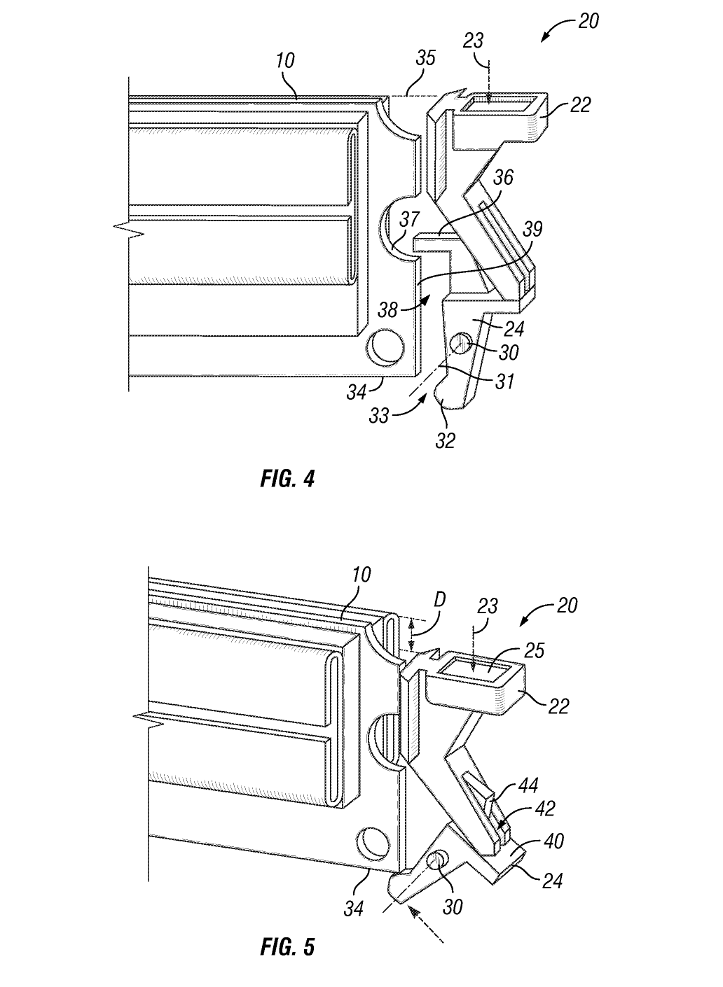

FIG. 4 is a partial perspective view of the latching mechanism 20 with the VLP DIMM 10 in a fully seated position within the connector and the linear actuator 22 in an upper position that corresponds to the VLP DIMM 10 being in the fully seated position. The connector body 21 (see FIG. 3A) is removed from this view to expose more detail of the VLP DIMM 10, the linear actuator 22, and the pivotable lever 24. Being in the fully seated position places the DIMM terminals in contact with the connector terminals, so that the VLP DIMM 10 may communicate with motherboard components. By inserting and moving the VLP DIMM 10 to its fully seated position the VLP DIMM 10 pushes against the end of the lever 24 and moves the lever to an upright position, which causes the linear actuator 22 to move to its upward position. As indicated at reference line 35, the top of the linear actuator 22 is no higher than the top of the connector when the linear actuator 22 is in its upper position. This ensures that the overall connector height, i.e. the perpendicular distance between the motherboard and the furthest point of the linear actuator 22 from the motherboard, is not increased by the presence of the latching mechanism 20.

The lever 24 has a circular pivot 30 that pivotally supports the lever on a portion of the connector body. The pivot 30 defines the pivot axis 31 about which the lever 24 rotates. A “card engagement portion,” which in this embodiment is a lip 32 formed on the distal end of the lever 24 (i.e. below the pivot axis 34), upwardly engages the lower edge of the card 10 and follows an arc about the pivot axis 31 when the lever 24 rotates. In the upright position of the lever 24 shown, there is a small gap 33 between the lip 32 and a lower edge 34 of the VLP DIMM 10. The gap 33 allows the VLP DIMM 10 to be positioned in its downward, fully seated position as shown without interference from the lever 24. Alternatively, there could be light contact between the lip 32 and the card 10 if that contact is not sufficient to raise or limit insertions of the VLP DIMM 10 while the latching mechanism 20 is at rest. When the lever 24 is subsequently rotated (in a clockwise direction as shown in FIG. 4) by pressing down on the linear actuator 22, the lip 32 will engage the lower edge 34 of the card 10 to raise the end of the VLP DIMM 10 shown. Another lever provided by the latching mechanism at the other end of the VLP DIMM 10 may similarly raise the other end of the VLP DIMM 10. The lever 24 also includes a retention tab 36 that is disposed within a standard notch 37 on the VLP DIMM 10. In the fully upright position of the lever 24 shown here, corresponding to the fully seated position of the VLP DIMM 10, the retention tab 36 helps secure the VLP DIMM 10 within the slot by preventing any unintended, appreciable upward movement of the VLP DIMM 10. In another respect, the lever 24 defines a channel 38 that retains an edge section 39 of the VLP DIMM 10 between the retention tab 36 from above and the card-engagement portion 32 from below.

FIG. 5 is a partially cutaway perspective view of the latching mechanism 20 with the linear actuator 22 in a lowered position, and with the VLP DIMM 10 in a correspondingly raised position that corresponds to the linear actuator 22 being in its lowered position. The linear actuator 22 has been moved downward a distance “D” in the direction indicated at 23, in response to a user pushing down at push point 25. As the linear actuator 22 is moved downward from the upper position of FIG. 4 toward the lowered position of FIG. 5, the linear actuator 22 causes the lever 24 to rotate downward while sliding along a contact surface 40 of the lever 24. Thus, the linear actuator 22 moves the lever 24 without requiring the linear actuator 22 to be mechanically coupled to the lever 24. With the linear actuator 22 being constrained to linear motion by the track 26 (FIG. 3B) and the lever 24 being constrained to rotational motion by the pivot 30, the linear actuator 22 is free to slide along the contact surface 40 as it engages the lever 24 to rotate the lever 24 about the axis 31. As the lever 24 rotates, the lip 32 of the lever 24 engages the lower edge 34 of the VLP DIMM 10 to raise and eject the VLP DIMM 10.

The linear actuator 22 and the lever 24 are described herein as being “interleaved” in that a slit-shaped relief channel 42 defined by the linear actuator 22 receives a “lever portion” 44 of the lever 24. The lever portion 44 extends through the relief channel 42 and is movably disposed within the relief channel 42. The relief channel 42 allows the linear actuator 24 to move downward to rotate the lever 24 without binding or locking up with the lever 24. As the linear actuator 22 is moved downward by the user to raise the VLP DIMM 10, and as the lever 24 correspondingly rotates about the pivot axis 31, the relief channel 42 provides clearance for the lever portion 44 to move within the slot 42. The latching mechanism 20 therefore requires less space to operate by virtue of this interleaved latching mechanism design. The interleaved design further reduces the required part clearance around the latching mechanism 20 to increase packaging density and allows for a reduced latching mechanism height so that the linear actuator 22 does not rise above the overall connector height when in its upper position of FIG. 4.

As described with reference to FIGS. 4 and 5, the latching mechanism 20 can be used to eject the VLP DIMM 10 by pressing on the push point 25 to move the linear actuator 22 toward the motherboard, from the position of FIG. 4 to the position of FIG. 5. Likewise, the latching mechanism 20 may also operate in “reverse,” in that inserting the VLP DIMM 10 into the connector and moving the VLP DIMM 10 to the fully seated position of FIG. 4 moves or returns the linear actuator 22 from its lowered position of FIG. 5 to its upper position of FIG. 4. With reference to FIG. 5, as the VLP DIMM 10 is urged downward into the slot of the connector, the VLP DIMM 10 engages the card engagement portion 34 of the lever 24 to rotate the lever 24 counter-clockwise about the pivot axis 31. As the lever 24 rotates counter-clockwise about the pivot axis 31, the contact surface 40 of the lever 22 urges the linear actuator 22 upward. As the VLP DIMM 10 is moved to the fully seated position in the connector, the linear actuator 22 returns to its upper position of FIG. 4, and the VLP DIMM 10 is again locked in place by the retention tab 36. Thus, no spring-return feature is needed on the latching mechanism 20. Rather, when the VLP DIMM 10 is removed completely, such as to inspect or replace the VLP DIMM 10, the linear actuator 22 may remain in the lowered position of FIG. 5 until the VLP DIMM 10 is re-inserted into the connector.

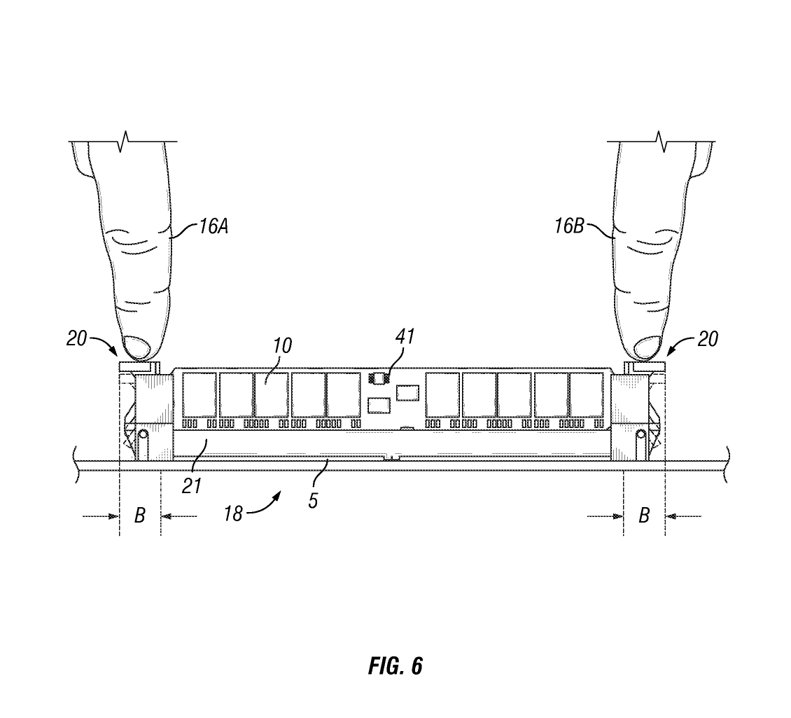

FIG. 6 is a side view of the VLP DIMM connector with the VLP DIMM positioned in the fully seated position, demonstrating the reduced size of the VLP DIMM connector as compared with the conventional VLP DIMM connector of FIG. 1. As shown, the user's fingers 16A, 16B push the linear actuators 22 directly downward toward the motherboard 5 at the push point 25 as the user begins to eject the VLP DIMM 10 from the connector. Thus, the latching mechanisms 20 do not move laterally outward like the levers 15 of the conventional connector 12 in FIG. 1. Therefore, the required clearance “B” need only take into account the width of the user's fingers 16A, 16B, as shown. No extra clearance is required about the connector to accommodate the movement of the latching mechanisms 20. Thus, clearance B is noticeably less than the clearance A. Also, the top of the latching mechanisms 20 are flush with the upper edge 41 of the VLP DIMM 10, due to the compact interleaved design of the linear actuator 22 and lever 24 (see FIG. 4). Thus, the overall height “C” of the connector and installed VLP DIMM 10 with respect to the motherboard 5 is not increased by the presence of the latching mechanisms 20.

The terms “comprising,” “including,” and “having,” as used in the claims and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition or step being referred to is an optional (not required) feature of the invention.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A connector for an electronic card, comprising:
a connector body configured for being secured to a circuit board and having a socket for removably receiving the electronic card in a seated position for electronic communication with the circuit board;
a lever pivotally coupled to an end of the connector body, and pivotable about a pivot axis into upward engagement with the electronic card at a card-engagement portion of the lever spaced from the pivot axis, to raise the electronic card away from the seated position; and
a linear actuator interleaved with the lever and movably secured on a track and linearly movable along the track toward the circuit board into engagement with another portion of the lever opposite the card-engagement portion with respect to the pivot axis, to cause the card-engagement portion of the lever to raise the electronic card from the seated position to a raised position.

2. The connector of claim 1, further comprising a relief channel defined by one of the lever and the linear actuator, wherein the other of the lever and the linear actuator is movably disposed in the relief channel through at least a portion of the range of movement of the lever and linear actuator that moves the electronic card from the seated position to the raised position.

3. The connector of claim 2, wherein the relief channel is defined by the linear actuator, and the lever rotates into the opening when the linear actuator is moved to raise the electronic card.

4. The connector of claim 2, wherein the relief channel comprises a slit defined by one of the lever and the linear actuator.

5. The connector of claim 1, wherein the linear actuator is not coupled to the lever, and the linear actuator slidably engages the lever when moving the electronic card between the seated position and the raised position.

6. The connector of claim 1, further comprising a retention tab on the lever configured for positioning in a notch on the electronic card when the electronic card is in the seated position, to retain the electronic card in the seated position.

7. The connector of claim 1, wherein the connector is configured for receiving a very low profile dual in-line memory module.

8. The connector of claim 1, wherein the socket of the connector is a slot oriented perpendicular to the circuit board and the linear actuator is moveable on the track perpendicularly toward the circuit board to raise the electronic card to the raised position.

9. A computer system, comprising:
a motherboard having a plurality of electronic motherboard components;
a memory module card having a plurality of electronic memory module terminals along an edge of the memory module card;
a memory module connector secured to the motherboard and having a slot-shaped memory module socket and a plurality of electronic socket terminals, the memory module socket configured for removably receiving an edge of the memory module, wherein the memory module is movable between a seated position in which the memory module terminals are in electrical contact with corresponding socket terminals and a raised position wherein the memory module terminals are separated from the socket terminals;
a lever pivotally coupled to an end of the connector body, and pivotable into engagement with the memory module card to move the memory module card within the memory module socket; and
a linear actuator movably secured on a track and linearly movable along the track into engagement with the lever to cause the lever to move the electronic card from the seated position to the raised position.

10. The connector of claim 9, further comprising a relief channel defined by one of the lever and the linear actuator, wherein the other of the lever and the linear actuator is movably disposed in the relief channel through at least a portion of the range of movement of the lever and linear actuator that moves the memory module card from the seated position to the raised position.

11. The computer system of claim 10, wherein the relief channel is defined by the linear actuator, and the lever rotates into the opening when the linear actuator is moved to raise the memory module card.

12. The computer system of claim 10, wherein the relief channel comprises a slit defined by one of the lever and the linear actuator.

13. The computer system of claim 9, wherein the linear actuator is not coupled to the lever, and the linear actuator frictionally, slidably engages the lever when moving the memory module card between the seated position and the raised position.

14. The computer system of claim 9, further comprising a retention tab on the lever configured for positioning in a notch on the memory module card when the memory module card is in the seated position, to retain the electronic card in the seated position.

15. The computer system of claim 9, wherein the memory module comprises a dual in-line memory module.

16. The computer system of claim 15, wherein the dual in-line memory module comprises a very low profile dual in-line memory module.

17. The computer system of claim 9, wherein the slot-shaped memory module socket is oriented perpendicular to the motherboard and the linear actuator is moveable on the track perpendicularly toward the motherboard to raise the memory module card to the raised position.

18. A method, comprising:
inserting an edge of a memory module card having a plurality of electronic memory module terminals into a slot-shaped memory module socket having a corresponding plurality of electronic socket terminals;
moving the memory module card within the memory module socket to a seated position in which the memory module terminals are in electrical contact with corresponding socket terminals;
while moving the memory module card to the seated position, engaging a lever with the memory module card to pivot the lever in a first direction about a pivot point; and
while pivoting the lever about the pivot point, engaging a linear actuator with the lever, to linearly move the linear actuator along a track to an upper position of the linear actuator.

19. The method of claim 18, further comprising:
pressing the linear actuator to move the linear actuator from the raised position to a lowered position;
while moving the linear actuator, engaging the lever with the linear actuator to pivot the lever about the pivot point in a second direction opposite the first direction; and
while pivoting the lever in the second direction, engaging the memory module card with the lever to move the memory module card from the seated position to a raised position separating electrical contact between the memory module terminals and the socket terminals.
